(19) United States
(12) Patent Application Publication
(10) Pub. No.: US 2013/0170106 A1
(43) Pub. Date: Jul. 4, 2013

(54) CELLULAR TELEPHONE SEPARATION APPARATUS

(71) Applicant: Peter M. Rubino, Concord, CA (US)

(72) Inventor: Peter M. Rubino, Concord, CA (US)

(21) Appl. No.: 13/342,340

(22) Filed: Jan. 3, 2012

(51) Int. Cl. H05K 7/00

(52) U.S. Cl. 361/679.01

(57) ABSTRACT

An apparatus for maintaining a physical separation between a cell phone and its user.

### TECHNICAL FIELD

This disclosure relates generally to an apparatus for maintaining a safe separation distance between a cellular telephone and its user.

### BACKGROUND

All cellular phones emit radio frequency (“RF”) energy. The question of whether such radiation poses any physical danger to users has been studied extensively, but no clear causation to specific ailments has been established. Nevertheless, the FCC has adopted a maximum safe limit of 1.6 watts/kilogram (defined as the Specific Absorption Rate or “SAR”) for cell phone operation in the United States. However, all cell phone manufacturers include a warning buried in their literature and/or packaging for new cell phones advising consumers to not hold or carry the device directly against the body, and that RF emissions of the cell phone could exceed the FCC limit if the cell phone is not held at least a short distance away from the body while it is transmitting. Recommended separation distances vary from about 15 mm (˜⅝ inch) to 25 mm (˜1 inch). Among other common warnings to minimize exposure to cell phone RF energy: if pregnant, avoid carrying cell phone next to abdomen; children should limit cell phone use since their skulls are smaller and thinner; and do not sleep with a cell phone next to your head or under the pillow.

There are a number of holsters, clips or pouches available for holding a cell phone, but none is designed to provide adequate separation distance. It would thus be desirable to have an apparatus to maintain a specified separation distance between a cell phone and the user.

### BRIEF SUMMARY

An apparatus for maintaining a safe separation distance between a cell phone device and its user. The apparatus includes at least one spacer wing adapted to be attached to the edge of a cellular device, wherein the spacer wing has a height chosen to provide a preset separation distance from the cellular device.

### BRIEF DESCRIPTION OF THE DRAWINGS

FIG. 1A is an exploded perspective view of one embodiment of an apparatus for maintaining a safe separation distance.

FIG. 1B is a perspective view of the components of FIG. 1A put together.

FIG. 1C is a detail view of one element of FIG. 1A.

FIG. 2A is an exploded perspective view of another embodiment of an apparatus for maintaining a safe separation distance.

FIG. 2B is a perspective view of the components of FIG. 2A put together.

FIG. 2C is a detailed view of a portion of FIG. 2A.

FIG. 3A is an exploded perspective view of another embodiment of an apparatus for maintaining a safe separation distance.

FIG. 3B is a perspective view of the components of FIG. 3A put together.

FIG. 3C is an exploded perspective view of another embodiment of an apparatus for maintaining a safe separation distance.

FIG. 3D is a perspective view of the components of FIG. 3C put together.

### DETAILED DESCRIPTION

According to scientific authorities, it is prudent for cell phone users to minimize exposure to the radiation that is transmitted and received by cellular devices, including telephones and other electronic hand-held devices which are designed to be in close contact with the user. Described herein is a safety spacer apparatus for providing a specified separation distance between a cellular telephone and its user.

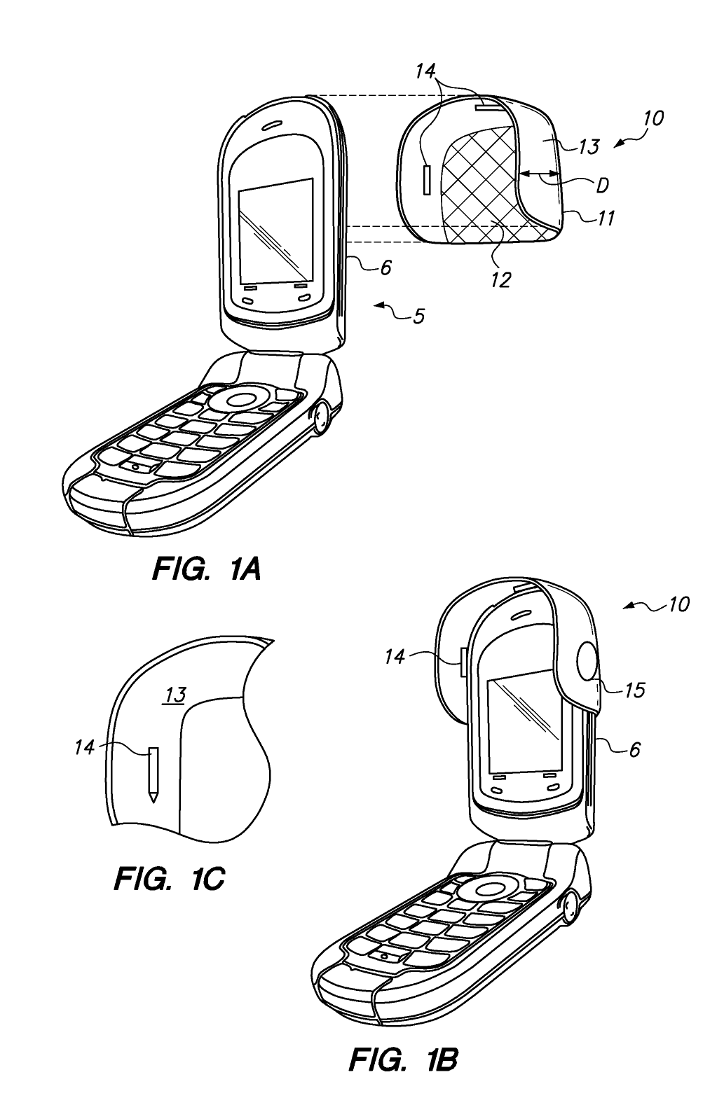

Referring to FIGS. 1A-1C, a first embodiment of a safety spacer 10 for a cellular phone 5 is illustrated. As shown, safety spacer 10 is a single piece 11 of material having a back portion 12 and a shoulder portion 13 extending orthogonally from the back portion for a predetermined distance D. The shoulder portion 13 includes locking tabs 14 spaced apart and protruding from the inside of the shoulder portion. The safety spacer 10 is secured to the cell phone 5 by snapping the locking tabs over the edge 6 of the cell phone. The safety spacer 10 also has cutouts 15 of various shapes and sizes, depending on the brand and model of the phone, which allow the user access to charging jacks, display screens, control buttons, “slide out keyboards” etc., as well as an opening for the camera lens, microphone, and speaker.

The safety spacer 10 is preferably a single integrated piece 11 of material, molded or otherwise formed to have a suitable shape and tab position. A wide variety of materials may be used, for example, molded plastic or composite materials, such as carbon fiber. However, the spacer could be formed from multiple pieces, and could be formed of rubber, metal, wood, fabric, mesh, gel, or any combination thereof, using known forming technologies. In fact, the safety spacer 30 could be integrally molded with the cellular device itself, or with a carrying case or body glove for the cellular device. Of necessity, a variety of shapes and locking tab positions would be required to accommodate the variety of phones available in the marketplace. For example, the shoulder portion may be rounded as shown, or squared off, depending on the application. Further, the tabs may be set closer to or further away from back portion 12, depending on the thickness of the edge 6 of phone 5. In one embodiment, the tabs 14 are formed as triangular protrusions, as shown in FIG. 1C, protruding a short distance from the inside surface, such as 1/16 inch, and separated from the back portion by the thickness of a phone edge, e.g., 3/16 inch or more. In yet another embodiment, the safety spacer 10 is constructed of rubber or a gel material and stretch fit onto the phone without any need for tabs. Also, the predetermined distance D can be set to any preferred value, such as ⅝ inch or larger values, to provide a desired separation distance between the cell phone and the user.

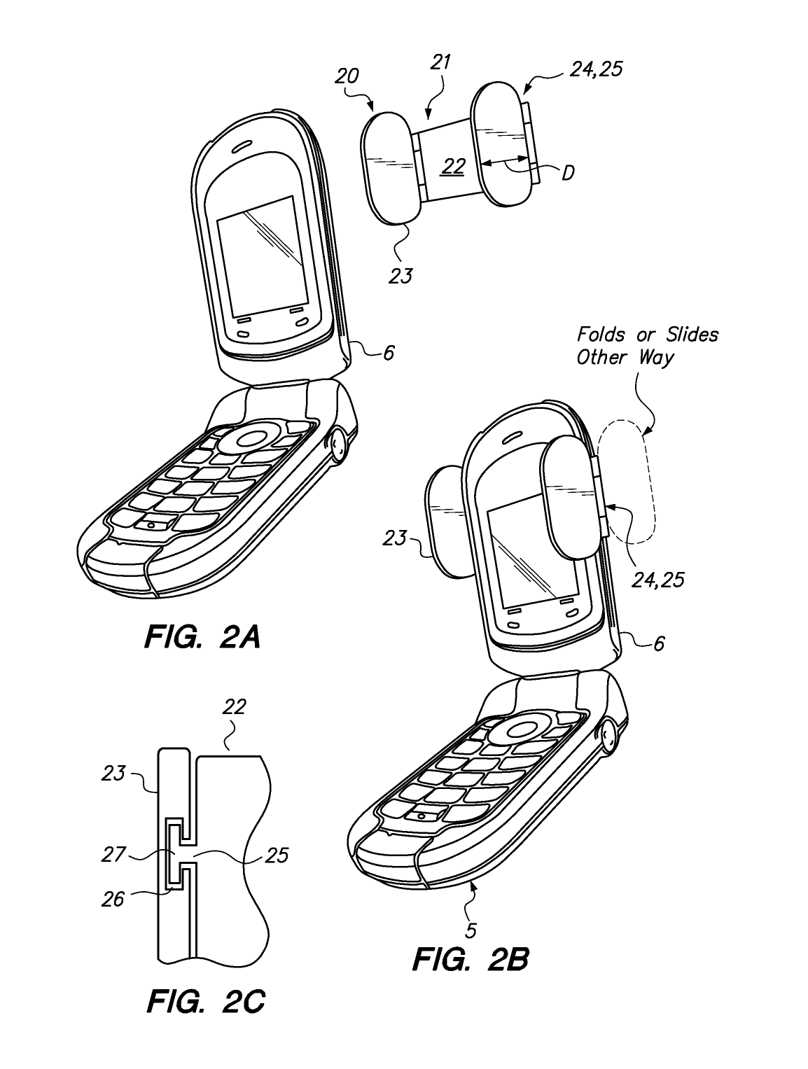

Referring now to FIGS. 2A-2C, a second embodiment of a safety spacer 20 for cellular phone 5 is illustrated. The safety spacer 20 is a single piece 21 having a back portion 22 and wing portions 23 attached to the back portion. The wing portions 23 are attached to the back portion 22, for example, by hinges 24, which may be molded as hinged flaps, or alternatively, by a sliding track 25 as shown in FIG. 2C. Each of the wing portions 23 has a height D. In FIG. 2C, the wing portion 23 has a channel 26 formed therein in the height direction to receive and slide over a rigid tab 27 formed on the back portion 22. Back portion 22 can be attached to the phone using a variety of methods such as locking tabs, self-adhesive pads, velcro, or stretch-fit when made from rubber or gel.

Advantageously, the folding/sliding wing portions 23 shown in FIG. 2B may be folded or slid either forward (solid line) or rearward (dashed line). When in use, the phone is open and the wing portions are folded or slid forward to provide a separation distance from the face of the phone. When the phone is closed, the wing portions are folded or slid rearward to provide a separation distance from the case of the phone, e.g., as it is held in a pocket or phone holder on the user's body.

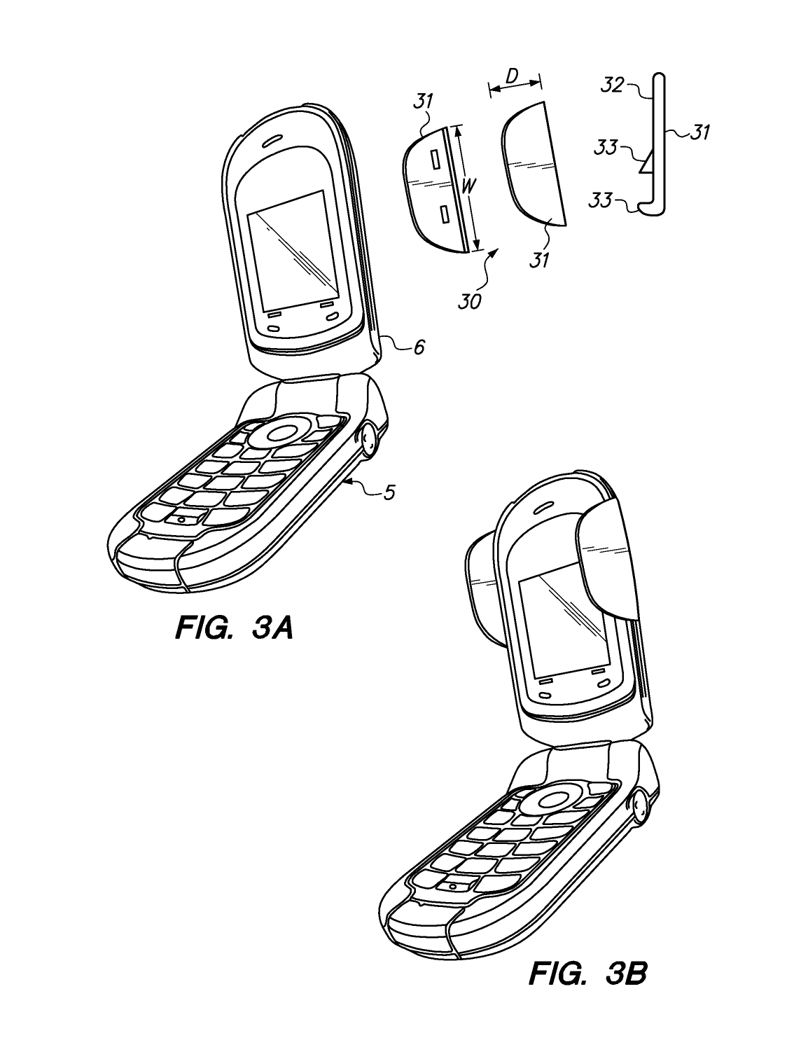

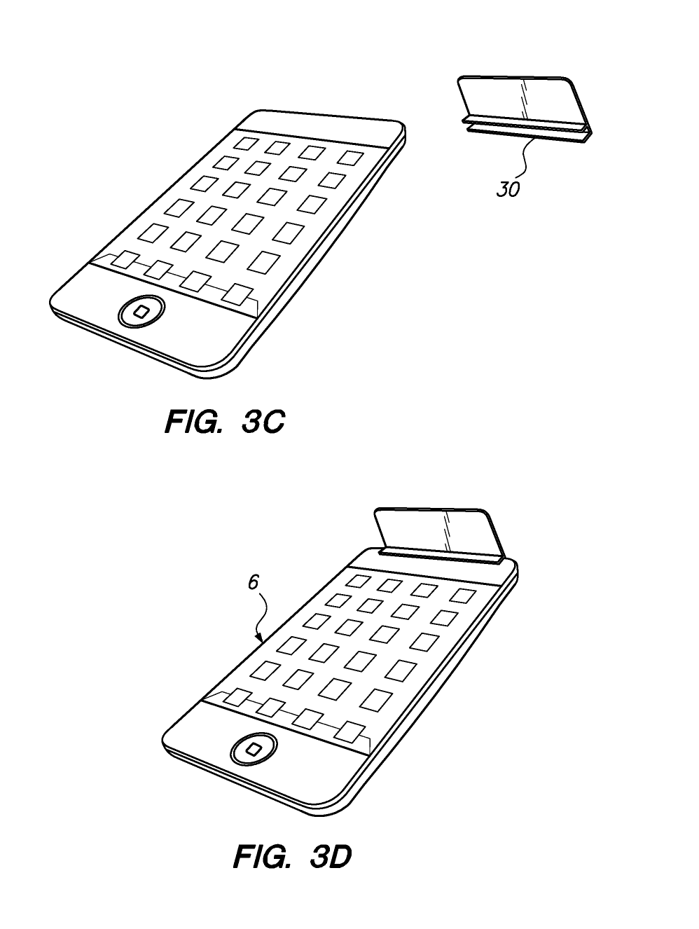

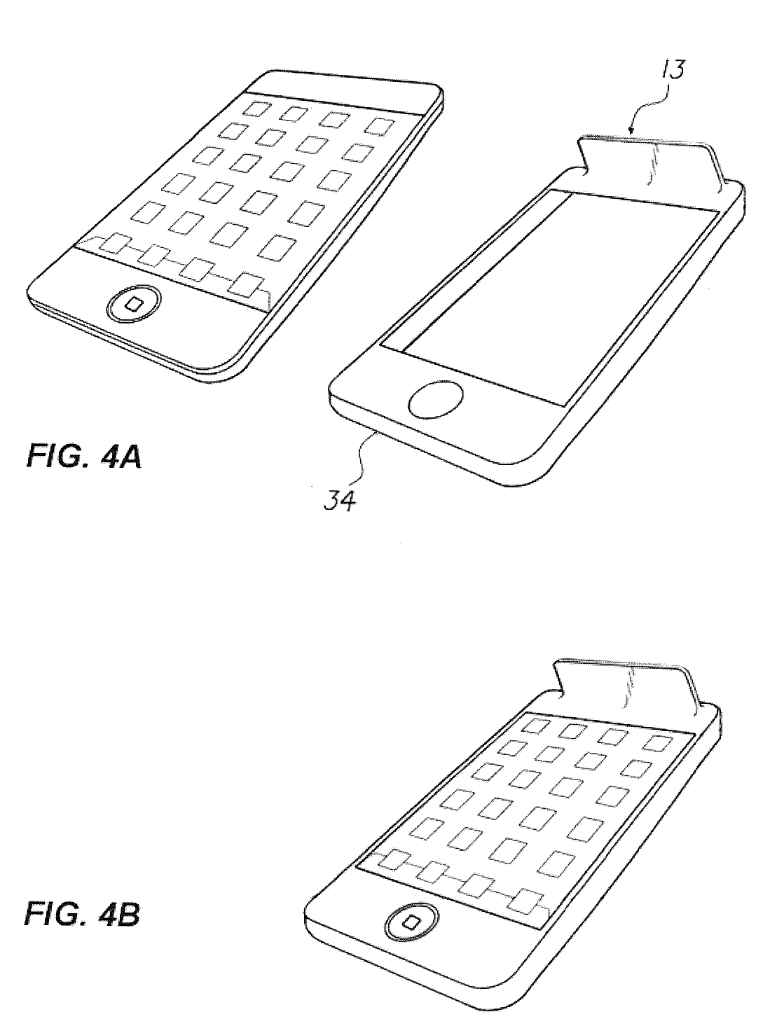

Referring now to FIGS. 3A-3B, a third embodiment of a safety spacer 30 for cellular phone 5 is illustrated. At least two safety spacers 30 are attached in opposing pairs to the edge 6 of phone 5. Each safety spacer 30 has a main wing portion 31 having a height D and a width W. On the inside surface 32 of the wing portion 31, a pair of protrusions 33 are formed, to provide a snap fit to the edge 6 of phone 5. The protrusions are preferably integrally formed as part of a single piece wing 31. The protrusions may be triangular protrusions as shown in FIG. 1C, or any other shape effective for the intended purpose.

Referring to FIGS. 3C-3D, a thin profile phone 5a is illustrated having a single safety spacer 30 attached to the top edge 6a of the phone. The safety spacer 30 is as described for FIGS. 3A-3B.

Although several embodiments are shown and described, there are numerous variations of shapes and sizes that are readily obvious, some designed to fit a wide variety of cell phone models while others are designed to fit only a specific model.

1. An apparatus for maintaining a safe separation distance from a cellular device, comprising:
at least one spacer wing adapted for attachment to an edge of the cellular device, the spacer wing having a height and a width, the height chosen to provide a preset separation distance from the cellular device.

2. The apparatus of claim 1, comprising:
at least one pair of the spacer wings, each spacer wing adapted for attachment to opposing edges of the cellular device.

3. The apparatus of claim 1, wherein the attachment for the spacer wing is hinged.

4. The apparatus of claim 1, wherein the attachment for the spacer wing is a slider.

5. The apparatus of claim 1, wherein the spacer wing is integrally molded with the cellular device.

6. The apparatus of claim 1, wherein the spacer wing is integrally molded with a carrying case for the cellular device.

7. The apparatus of claim 1, wherein the spacer wing includes at least one cutout for accessing hardware features of the cellular device.

8. The apparatus of claim 1, further comprising a pair of protrusions formed along the width near a bottom of the spacer wing, the protrusions sized to snap fit onto the edge of the cellular device.

9. The apparatus of claim 2, further comprising a back portion coupling the pair of spacer wings.

10. An apparatus for maintaining a safe separation distance from a cellular device, comprising
a shoulder portion coupled to a back portion;
wherein the shoulder portion extends orthogonally from the back portion with a height chosen to provide a preset separation distance and includes at least one latch located just above the coupling of the shoulder portion to the back portion, the latch configured to attach to the edge of the cellular device.

11. The apparatus of claim 10, wherein the shoulder portion and back portion are formed to fit snugly on the cellular device.

12. The apparatus of claim 10, wherein the latch comprises at least one protrusion located just above the coupling and sized such that the edge of the cellular device will be snap fit between the protrusion and the back portion.

13. The apparatus of claim 10, wherein the back portion is formed to extend between ¼ inch and 1 ¼ inch beyond the speaker surface area of the cellular device.

14. The apparatus of claim 10, wherein the shoulder portion and back portion include a plurality of cutouts for accessing hardware features of the cellular device.

15. The apparatus of claim 10, wherein the shoulder portion is integrally molded with the cellular device.

16. The apparatus of claim 10, wherein the shoulder portion is integrally molded with a carrying case for the cellular device.
